(19) United States
(12) Patent Application Publication
(10) Pub. No.: US 2020/0270738 A1
(43) Pub. Date: Aug. 27, 2020

(54) METHOD FOR PRODUCING A BASE PLATE FOR AN ELECTRONIC MODULE

(71) Applicant: Doduco Solutions GmbH, Profzheim (DE)

(72) Inventors: Joachim Ganz, Kapfenhardt (DE); Roland Hoffmann, Pforzheim (DE); Uwe Dreissigacker, Engelsbrand (DE)

(73) Assignee: Doduco Solutions GmbH, Pforzheim (DE)

(21) Appl. No.: 15/929,581

(22) Filed: May 11, 2020

Related U.S. Application Data
(63) Continuation of application No. PCT/EP2018/078424, filed on Oct. 17, 2018.

(30) Foreign Application Priority Data
Nov. 13, 2017 (DE) 102017126590.2

(51) Int. Cl. C23C 14/02; C23C 14/04; C23C 14/18

(52) U.S. Cl. CPC C23C 14/025; C23C 14/18; C23C 14/022; C23C 14/042

(57) ABSTRACT

A method for producing a base plate for an electronic module is where a plate made of a composite material, which contains a metallic component based on aluminum and a non-metallic component, is coated with a solderable layer. The carrier layer and the cover are deposited by means of physical vapour deposition.

### CROSS-REFERENCE TO RELATED APPLICATIONS

This continuation application claims priority to PCT/EP2018/078424 filed on Oct. 17, 2018 which has published as WO 2019/091734 A1 and also the German application number 10 2017 126 590.2 filed on Nov. 13, 2017, the entire contents of which are fully incorporated herein with these references.

### DESCRIPTION

### Field of the Invention

The invention relates to a method for producing a base plate for an electronic module.

### Background of the Invention

Increased demands on the base plates of electronic modules with regard to thermal conductivity, a favourable coefficient of thermal expansion, together with mechanical stability, and the lowest possible weight, have led to the increasing use of plates made of composite materials that contain a metallic component based on aluminium, and a non-metallic component such as SiC or graphite. These composite materials take the form of particle composite materials. Particle composite materials are sometimes also referred to as matrix composite materials.

The composite materials commonly used for base plates of electronic modules, which, in addition to aluminium, contain a non-metallic component such as silicon carbide or graphite, are difficult to solder. In the production of base plates for electronic modules, plates made of such a composite material are therefore coated with an intermediate layer based on nickel, and an easily solderable cover layer based on copper or a precious metal.

For this purpose, the surface of the composite material plate is first treated with pickling media containing fluorine, so as to remove silicon carbide or other non-metallic components from the surface of the plate. A nickel layer is then wet-chemically deposited on the remaining metallic surface. In a further galvanic process step, the nickel layer is first covered with a nickel layer, and then with a cover layer based on copper or a precious metal.

The pickling step is laborious, but necessary, because galvanically deposited nickel layers have poor adhesion to silicon carbide or other non-metallic components of the composite material. The removal of non-metallic grains on the surface of the composite material as completely as possible requires relatively long exposure times to aggressive pickling media. A good adhesion of the nickel layer is therefore accompanied by increasingly longer and more laborious preparation steps. A further problem is that the nickel layer can store hydrogen during the galvanic coating process, which leads to pores and an uneven layer formation, as well as blowholes during subsequent soldering.

### SUMMARY OF THE INVENTION

An object of the present invention is to demonstrate a way of improving the quality of the coatings and saving costs in the production of a base plate for an electronic module.

This object is achieved by a method with the features specified in claim 1. Advantageous refinements of the invention are the subject matter of dependent claims.

In an inventive method for producing a base plate for an electronic module, a plate made of a composite material, which contains a metallic component based on aluminium and a non-metallic component, is coated by means of physical vapour deposition (PVD). This has the advantage of increasing the speed of the process, which enables cost savings, and avoids the problem of hydrogen deposition in the nickel layer. A nickel layer deposited by PVD is therefore easily solderable, so that a layer based on copper or a precious metal is no longer necessary. In accordance with the invention, the solderable layer can therefore be a nickel layer, or a layer based on copper or a precious metal. The layer based on copper or a precious metal can be deposited onto a nickel layer, onto an adhesive layer, or directly onto the plate. Another advantage is that by using masks the coating can easily be limited to those areas in which a coating is actually needed.

Surprisingly, an even, closed layer can be achieved by using PVD, and with much thinner layer thicknesses than when using wet chemical and galvanic coating processes. The sum of all layers deposited on the plate therefore preferably has a thickness of only 5 μm or less, for example 3 μm or less, in particular 0.5 μm to 1.5 μm. Thinner layers enable faster production and thus further cost savings.

In an advantageous refinement of the invention provision is made for an adhesive layer, based, for example, on titanium, tungsten, molybdenum and/or chromium, to be deposited on the plate by means of PVD before the solderable layer is deposited. The solderable layer can be deposited directly onto the adhesive layer, or onto an intermediate layer between the adhesive layer and the solderable layer, for example one based on nickel. This has the advantage that the adhesion of the layer or layers can thereby be improved. Layers based on titanium, tungsten, molybdenum and/or chromium adhere to aluminium, as well as to non-metallic components of the plate, such as SiC or carbon, in particular graphite. A laborious pickling step to remove non-metallic grains from the surface of the plate is therefore no longer necessary.

The invention also relates to an electronic module with a base plate produced by the inventive method, and an electronic component soldered onto the cover layer of the base plate. For example, the component can contain a transistor, in particular an insulated-gate bipolar transistor (IGBT).

### DETAILED DESCRIPTION OF THE PREFERRED EMBODIMENTS

Further details and advantages of the invention are described below with the aid of an example of embodiment:

In the inventive production of a base plate for an electronic module, the plate made of a particle composite material, which contains a metallic component based on aluminium, and a non-metallic component, based, for example, on SiC or carbon (such as graphite, graphene or C-nanotubes), can first be wet-chemically pretreated, wherein the plate is washed and degreased. As a further pretreatment step, the surface of the plate may be treated by ion etching.

An adhesive layer based on titanium, tungsten, molybdenum, or chromium is then deposited onto the plate by means of PVD. An intermediate layer based on nickel is then deposited onto the bonding layer by means of PVD, and a cover layer based on copper or a precious metal, for example silver or gold, is then deposited onto the intermediate layer by means of PVD. When depositing the various layers by means of PVD, masks can be used so as to omit specific areas of the plate from the coating process.

The adhesive layer preferably has a thickness of less than 1 μm, for example from 0.05 μm to 0.5 μm, in particular from 0.05 μm to 0.2 μm. The intermediate layer should be thicker than the adhesive layer. The intermediate layer preferably has a thickness of 2 μm or less, for example from 0.5 μm to 1.5 μm. The cover layer preferably has a thickness of less than 1 μm, for example from 0.05 μm to 0.5 μm.

The composite material of the plate can be, for example, AlSiC, in particular AlSiC-9. AlSiC-9 contains 37% Al and 63% SiC by volume. Another possibility is for the composite material to be AlC, in particular AlC with a graphite component of less than 30% carbon by weight.

What is claimed is:

1. A method for producing a base plate for an electronic module, the method comprising the steps of:
providing a plate of a composite material, which contains a metallic component based on aluminium, and a non-metallic component; and
coating the plate with a solderable layer;
wherein the solderable layer is deposited by means of physical vapour deposition.

2. The method according to claim 1, wherein the solderable layer is a nickel layer, or a layer based on copper or a precious metal.

3. The method according to claim 1, wherein the solderable layer is a layer based on copper or a precious metal, which is deposited onto an intermediate layer based on nickel deposited by means of physical vapour deposition.

4. The method according to claim 1, wherein an adhesive layer is deposited onto the plate by means of physical vapour deposition, before the solderable layer is deposited.

5. The method according to claim 4, wherein the adhesive layer is a layer based on titanium, tungsten, molybdenum, and/or chromium.

6. The method according to claim 1, wherein the non-metallic component of the composite material is silicon carbide or carbon.

7. The method according to claim 1, including the step of ion etching of the plate before the coating process.

8. The method according to claim 1, wherein the step of coating the plate includes coating with the aid of a mask, where areas of the plate are omitted from coating by the mask.

9. A method for producing a base plate for an electronic module, the method comprising the steps of:
providing a plate of a composite material, which contains a metallic component based on aluminium, and a non-metallic component;
ion etching the plate;
depositing by means of physical vapour deposition a nickel layer onto the base plate; and
depositing by means of physical vapour deposition a solderable layer based on copper or a precious metal onto the nickel layer.
